(19) United States
(12) Patent Application Publication
(10) Pub. No.: US 2017/0203238 A1
(43) Pub. Date: Jul. 20, 2017

(54) TARGET GENERATION DEVICE, AND METHOD FOR MANUFACTURING FILTER STRUCTURE

(71) Applicant: Gigaphoton Inc., Tochigi (JP)

(72) Inventors: Takanobu ISHIHARA, Oyama-shi (JP); Hakaru MIZOGUCHI, Oyama-shi (JP)

(73) Assignee: Gigaphoton Inc., Tochigi (JP)

(21) Appl. No.: 15/476,502

(22) Filed: Mar. 31, 2017

Related U.S. Application Data
(63) Continuation of application No. PCT/JP2014/079350, filed on Nov. 5, 2014.

(51) Int. Cl. B01D 29/01; B01D 29/15; H01L 21/027; B01D 29/11; B01D 39/20; B05B 9/03; B01D 29/05; B01D 29/23

(52) U.S. Cl. CPC B01D 29/014; B01D 29/05; B01D 29/012; B01D 29/15; B01D 29/23; B01D 29/111; B01D 39/2003; B05B 9/03; H01L 21/027; B01D 2201/0423; B01D 2201/188; B01D 2201/325; B01D 2239/065; B01D 2239/10; B01D 2239/1216

(57) ABSTRACT

A target generation device may include a filter structure, a flange, a tank unit, and a nozzle section. The flange may accommodate the filter structure and contain a flow path passing through the filter structure. The tank unit may contain a space in communication with the flow path in the flange and store a predetermined target material. The nozzle section may be provided to the flange and in communication with the space in the tank unit through the flow path in the flange. The filter structure according to one embodiment of the present disclosure may include a filter of a porous material and a socket integrally formed with the filter.

### CROSS-REFERENCE TO RELATED APPLICATIONS

The present application is a continuation application of International Application No. PCT/JP2014/079350 filed on Nov. 5, 2014. The content of the application is incorporated herein by reference in its entirety.

### BACKGROUND

1. Technical Field

The present disclosure relates to a filter structure, a target generation device, and a method for manufacturing the filter structure.

2. Related Art

In recent years, as the semiconductor processes are moved to finer design rules, transfer patterns for photolithography in semiconductor processes have been rapidly shifted to finer designs. In the next generation, fine patterning of 60 nm-45 nm or fine patterning of 32 nm or less will be required. To meet the requirement for fine patterning of 32 nm or less, for example, the development of a stepper has been expected which is a device for generating extreme ultraviolet (EUV) light of a wavelength of about 13 nm combined with reduced projection reflective optics.

The following three devices have been proposed as EUV light generating devices: laser produced plasma (LPP) devices which use plasma generated by irradiation of target substances with laser light, discharge produced plasma (DPP) devices which use plasma generated by discharge, and synchrotron radiation (SR) devices which use synchrotron orbital radiation.

### CITATION LIST

### Patent Literature

Patent Literature 1: Japanese Patent No. 4854024

Patent Literature 2: Japanese Patent Application Laid-Open No. 2013-140771

Patent Literature 3: Japanese National Publication of International Patent Application No. 2008-532228

Patent Literature 4: U.S. Patent Application Publication No. 2004/0071266

### SUMMARY

A filter structure (110, 110A, 110B, 120, 130, 150, 160) according to one embodiment of the present disclosure may include a filter (111, 121, 121A, 121B, 131, 151), and a socket (115, 126, 144, 156). The filter (111, 121, 121A, 121B, 131, 151) may contain a porous material. The socket (115, 126, 144, 156) may be integrally formed with the filter.

A target generation device (26) according to other embodiments of the present disclosure may include the above filter structure, a flange (301), a tank unit (260), and a nozzle section (266). The flange (301) may accommodate the filter structure and contain a flow path passing through the filter structure. The tank unit (260) may contain a space in communication with the flow path in the flange and store a predetermined target material. The nozzle section (266) may be provided to the flange and in communication with the space in the tank unit through the flow path in the flange.

A method for manufacturing a filter structure according to other embodiments of the present disclosure is a method for manufacturing a filter structure having a filter of a porous material and may include stacking the filter partly covered by a masking member; thermally spraying an outer surface of the filter partly covered by the masking member with a material (1008) having substantially the same coefficient of thermal expansion as the filter; processing the material to partly expose the masking member; and removing the masking member.

### BRIEF DESCRIPTION OF THE DRAWINGS

Embodiments of the present disclosure will now be described with reference to the attached drawings as illustrative only.

FIG. 1 schematically illustrates a configuration of an illustrative LPP EUV light generation system;

FIG. 2 is a schematic view of an example of a schematic configuration of a target generation device including a target supply unit illustrated in FIG. 1;

FIG. 3 is a cross-sectional view of an example of a schematic configuration of a filter portion;

FIG. 4 is a cross-sectional view of an example of a schematic configuration of a filter portion according to Embodiment 1;

FIG. 5 is a cross-sectional view of an example of a schematic configuration of a multilayer filter according to the first modification of Embodiment 1;

FIG. 6 is a cross-sectional view of an example of a schematic configuration of a multilayer filter according to the second modification of Embodiment 1;

FIG. 7 is a cross-sectional view of an example of a schematic configuration of a filter portion according to Embodiment 2;

FIG. 8 is a perspective view of an example of a schematic configuration of a filter structure illustrated in FIG. 7;

FIG. 9 illustrates a cross-sectional structure of the multilayer filter in the filter structure in FIG. 8 along a face perpendicular to a direction in which an internal space extends;

FIG. 10 illustrates a cross-sectional structure of a multilayer filter of the first modification of Embodiment 2 along a face perpendicular to the direction in which the internal space extends;

FIG. 11 illustrates a cross-sectional structure of a multilayer filter of the second modification of Embodiment 2 along a face perpendicular to the direction in which the internal space extends;

FIG. 12 is a cross-sectional view of an example of a schematic configuration of a filter portion according to Embodiment 3;

FIG. 13 illustrates a cross-sectional structure of the multilayer filter in the filter portion in FIG. 12 along a face perpendicular to the direction in which the internal space extends;

FIG. 14 is a cross-sectional view of an example of a schematic configuration of a filter portion according to Embodiment 4;

FIG. 15 is a cross-sectional view of an example of a schematic configuration of a filter portion according to Embodiment 5;

FIG. 16 is a cross-sectional view of an example of a schematic configuration of a filter portion according to Embodiment 6;

FIG. 17 is a flow chart of an example process for manufacturing a filter structure according to Embodiment 6 by thermal spraying;

FIG. 18 is a process cross-sectional view (1) illustrating the manufacturing process illustrated in FIG. 17;

FIG. 19 is a process cross-sectional view (2) illustrating the manufacturing process illustrated in FIG. 17;

FIG. 20 is a process cross-sectional view (3) illustrating the manufacturing process illustrated in FIG. 17;

FIG. 21 is a process cross-sectional view (4) illustrating the manufacturing process illustrated in FIG. 17;

FIG. 22 is a process cross-sectional view (5) illustrating the manufacturing process illustrated in FIG. 17; and

FIG. 23 is a process cross-sectional view (6) illustrating the manufacturing process illustrated in FIG. 17.

### EMBODIMENTS

Contents
1. Overview
2. General description of EUV light generation system
   2.1 Configuration
   2.2 Operation
3. Terms
   3.1 Terms in Section 2
   3.2 Terms in disclosures
4. Target generation device
   4.1 Configuration
   4.2 Operation
5. Filter portion
   5.1 Configuration
   5.2 Operation
   5.3 Problem to be Solved
6. Embodiment 1
   6.1 Configuration
   6.2 Effect
7. Modifications of Embodiment 1
   7.1 Configuration
   7.1.1 First modification
   7.1.2 Second modification
   7.1.3 Other modifications
   7.2 Effect
8. Embodiment 2
   8.1 Configuration
   8.2 Effect
9. Modifications of Embodiment 2
   9.1 Configuration
   9.1.1 First modification
   9.1.2 Second modification
   9.2 Effect
10. Embodiment 3
   10.1 Configuration
   10.2 Effect
11. Embodiment 4
   11.1 Configuration
   11.2 Effect
12. Embodiment 5
   12.1 Configuration
   12.2 Effect
13. Embodiment 6
   13.1 Configuration
   13.2 Effect
14. Materials
   14.1 Materials for socket and cap
   14.2 Filter material
15. Process for manufacturing filter structure by thermal spraying

Embodiments of the present disclosure will now be described in detail with reference to the drawings. The embodiments below are to be taken as merely examples of the present disclosure and do not limit the scope of the present disclosure. In addition, not all the configuration and the operation described in each embodiment are not necessarily essential to the configuration and the operation of the present disclosure. It should be noted that the same components are denoted as the same reference numeral and overlaps between their descriptions will be omitted.

### 1. Overview

An embodiment of the present disclosure may relate to supply of a target material for EUV light generation, particularly to a target generation device for supplying a target material to a chamber for EUV light generation. During supply of target material, a target material should be accurately and stably supplied to a region where a plasma that radiates EUV light is generated. However, particles present in the target material and the like may destabilize the supply of the target material to the plasma generated region. In view of this, embodiments of the present disclosure described below illustrate a target generation device for stable supply of a target material. Note that the present disclosure should not be limited to these factors and may relate to any factors for a target material for EUV light generation.

### 2. General description of EUV light generation system

2.1 Configuration

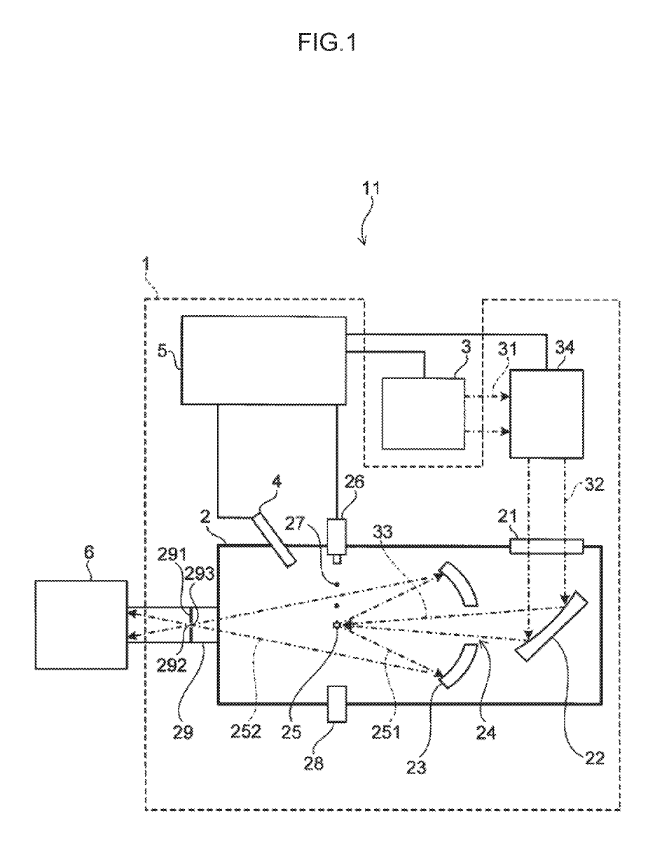

FIG. 1 schematically illustrates a configuration of an illustrative LPP EUV light generation system. An EUV light generating device 1 may be used with at least one laser apparatus 3. In this application, a system including the EUV light generating device 1 and the laser apparatus 3 is referred to as an EUV light generation system 11. As illustrated in FIG. 1 and described later in detail, the EUV light generating device 1 may include a chamber 2 and a target supply unit 26. The chamber 2 may be a hermetically sealable. The target supply unit 26 may be mounted, for example, passing through the wall of the chamber 2. A target substance material supplied from the target supply unit 26 may be tin, terbium, gadolinium, lithium, xenon, or any combination of two or more of them; however, this is not necessarily the case.

The wall of the chamber 2 may have at least one through hole. The through hole may be provided with a window 21 and pulse laser light 32 from the laser apparatus 3 may pass through the window 21. The chamber 2 may contain an EUV condenser mirror 23 having a spheroidal reflective surface. The EUV condenser mirror 23 may have first and second focuses. For example, a multi-layer reflective film with alternating molybdenum and silicon layers may be formed on the surface of the EUV condenser mirror 23. For example, the first focus of the EUV condenser mirror 23 is preferably located in a plasma generated region 25 and its second focus is preferably located at an intermediate light collection point (IF) 292. A through hole 24 may be provided in the center of the EUV condenser mirror 23 and pulse laser light 33 may pass through the through hole 24.

The EUV light generating device 1 may include an EUV light generation control device 5, a target sensor 4, and other components. The target sensor 4 may have an imaging function and be configured to detect the presence, path, position, speed, and other information on the target 27.

The EUV light generating device 1 may further include a connecting portion 29 that establishes communication between the interior of the chamber 2 and the interior of a stepper 6. The connecting portion 29 may have a wall 291 with an aperture 293 in the interior. The wall 291 may be disposed so that its aperture 293 can be in the position of the second focus of the EUV condenser mirror 23.

The EUV light generating device 1 may further include a laser light travel direction controller 34, a laser light condenser mirror 22, a target recovery unit 28 for recovery of the target 27, and other components. The laser light travel direction controller 34 may include an optical element for defining the travel direction of the laser light, and an actuator for adjusting the position and the posture of the optical element.

2.2 Operation

As illustrated in FIG. 1, pulse laser light 31 from the laser apparatus 3 may pass through the laser light travel direction controller 34 and then enter the interior of the chamber 2 through the window 21 as the pulse laser light 32. The pulse laser light 32 may travel to an inside of the chamber 2 along at least one laser light path, be reflected by the laser light condenser mirror 22, and be radiated to at least one target 27 as pulse laser light 33.

The target supply unit 26 may be configured to output the target 27 to the plasma generated region 25 in the chamber 2. The target 27 may be irradiated with at least one pulse of the pulse laser light 33. The target 27 irradiated with the pulse laser light becomes plasma which can generate emitted light 251. EUV light 252 contained in the emitted light 251 may be selectively reflected off the EUV condenser mirror 23. The EUV light 252 reflected off the EUV condenser mirror 23 may be collected at the intermediate light collection point 292 and then fed to the stepper 6. It should be noted that a single target 27 may be irradiated with more than one pulses of pulse laser light 33.

The EUV light generation control device 5 may be configured to control the entire EUV light generation system 11. The EUV light generation control device 5 may be configured to process image data or the like of the target 27 captured by the target sensor 4. Further, the EUV light generation control device 5 may be configured to control the timing and direction of the ejection of the target 27, for example. Moreover, the EUV light generation control device 5 may be configured to control the timing of lasing by the laser apparatus 3, the travel direction of the pulse laser light 32, and the position where the pulse laser light 33 is collected, for example. These different controls are illustrative only and other controls may be optionally added.

### 3. Terms

3.1 Terms in Section 2

The terms used in the present disclosure are defined as follows. A “droplet” may be a drop of a dissolved target material. The shape of a droplet may be generally spherical. A “plasma generated region” may be a three-dimensional space predetermined as a space where plasma is generated.

3.2 Terms in Disclosures

In the description below, a cross section or cross-sectional view of each component of a target generation device may be, unless otherwise designated, a cross section or cross-sectional view including the paths of droplets ejected from a nozzle hole. A “dense body” may be a poly-crystal or single-crystal body in which the orientations of particles of a ceramic are aligned for densification. A “multilayer direction” may be a direction in which the layers of a multilayer body are stacked. An “upstream” and “downstream” of a flow path may refer to an “upstream” and “downstream” of the flow of a fluid in the flow path.

### 4. Target Generation Device

An example of a target generation device including the target supply unit 26 illustrated in FIG. 1 will now be described in detail referring to a drawing.

4.1 Configuration

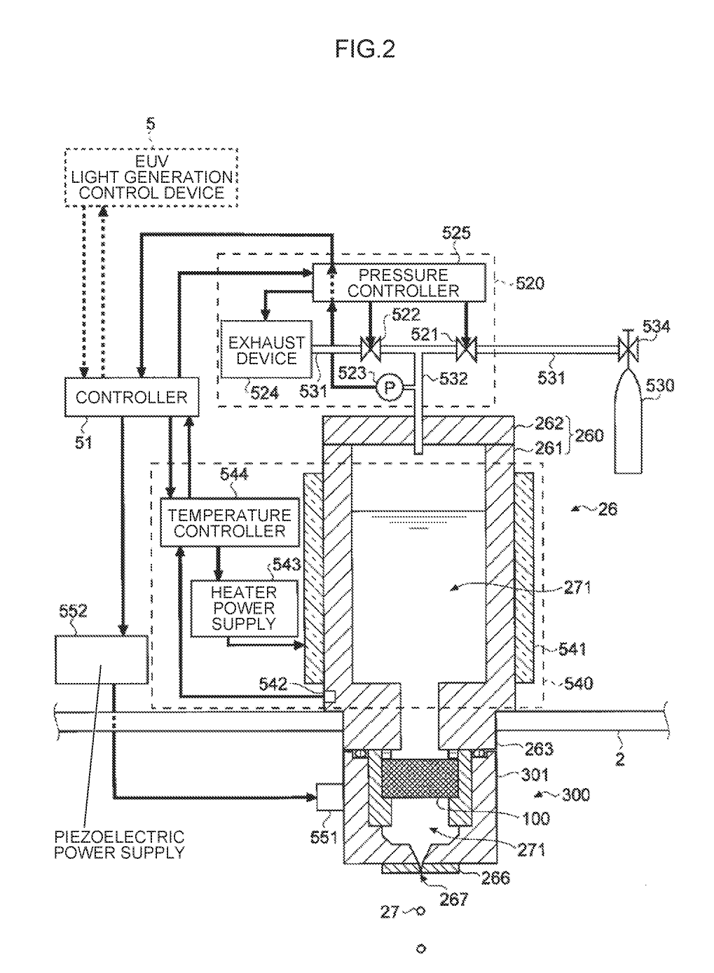

FIG. 2 is a diagram of an example of the schematic configuration of the target generation device including the target supply unit 26 illustrated in FIG. 1. As illustrated in FIG. 2, the target generation device may include, in addition to the target supply unit 26, a pressure adjuster 520, a temperature-controllable device 540, a controller 51, and a piezoelectric power supply 552.

The target supply unit 26 may include a tank unit 260, a filter portion 300, a nozzle section 266, and a piezoelectric element 551.

The tank unit 260 may include a tank 261 and a lid 262. The tank unit 260 may store a target material 271. The target material 271 may be tin (Sn) or other metal targets. A cylindrical projection 263 projecting toward a chamber 2 (see FIG. 1) may be provided under the tank 261. This projection 263 may be formed integrally with or independently of the tank 261.

The materials for the tank 261 and the projection 263, and the lid 262 and the filter portion 300 may have low reactivity with the target material 271. This material having low reactivity with the target material 271 may be molybdenum (Mo), for example.

The filter portion 300 containing a multilayer filter 100 may be provided at the bottom of the projection 263. A flow path passing from the tank 261 to the nozzle section 266 may be formed in the interiors of the projection 263 and the filter portion 300. The bottom of the filter portion 300 has an opening of this flow path. The details of the filter portion 300 will be mentioned later.

The nozzle section 266 may be provided covering the opening at the bottom of the filter portion 300. The nozzle section 266 may have a nozzle hole 267. The nozzle hole 267 may be in communication with the flow path in the filter portion 300. The diameter of the nozzle hole 267 may be, for example, 2 to 6 μm. The material for the nozzle section 266 may be molybdenum (Mo).

The pressure adjuster 520 may include a pressure controller 525, an exhaust device 524, valves 521 and 522, and a pressure sensor 523. The exhaust device 524 may be connected to an inert gas cylinder 530 via gas piping 531. The cylinder 530 may have a valve 534 for adjusting the supply gas pressure.

The valves 521 and 522 may be provided in two portions on the gas piping 531. The gas piping 531 between the valves 521 and 522 may branch to gas piping 532. The gas piping 532 may be in communication with the tank unit 260. The pressure sensor 523 may be provided to the gas piping 532.

The temperature-controllable device 540 may include a heater 541, a temperature sensor 542, a heater power supply 543, and a temperature controller 544.

The heater 541 may be provided to heat the target material 271 in the tank unit 260. The heater 541 may be provided on the outer periphery of the tank 261. The temperature sensor 542 may be provided to measure the temperature of the tank unit 260 or the target material 271 in the tank unit 260. The temperature sensor 542 may be provided on the side surface of the tank 261. The heater power supply 543 may supply current to the heater 541.

An output signal line extending from the controller 51 may be connected to the piezoelectric power supply 552, the temperature controller 544, the pressure controller 525, and the EUV light generation control device 5. An input signal line extending to the controller 51 may be connected to the temperature controller 544, the pressure controller 525, and the EUV light generation control device 5.

4.2 Operation

The controller 51 of the target generation device illustrated in FIG. 2 may conduct the following process upon reception of a droplet ejection preparation signal from the EUV light generation control device or a controller of an external device.

In particular, the controller 51 may first control the pressure adjuster 520 to exhaust the gas in the tank unit 260. Meanwhile, the pressure controller 525 in the pressure adjuster 520 may drive the exhaust device 524 with the valve 521 closed and the valve 522 opened.

Subsequently, the controller 51 may control the temperature-controllable device 540 so as to melt the target material 271 in the tank unit 260. Meanwhile, the temperature controller 544 of the temperature-controllable device 540 may drive the heater 541 so that values detected by the temperature sensor 542 can be at or above a predetermined temperature Top. The predetermined temperature Top may be at or above the temperature of the melting point of tin (a temperature of 232° C.) when the target material 271 is tin (Sn), for example. In addition, the predetermined temperature Top may be a range of temperature. The range of temperature may be from 240° C. to 290° C., for example.

The controller 51 may then determine if the values detected by the temperature sensor 542 are at or above the predetermined temperature Top for a predetermined time. If so, the controller 51 may provide the EUV light generation control device 5 or the controller in the external device with a notification that droplets are ready to be ejected.

Subsequently, upon reception of a droplet ejection signal requiring the ejection of the droplets 27, the controller 51 may instruct the pressure adjuster 520 to increase the pressure in the tank unit 260 to a predetermined pressure P (e.g., 10 megapascals (MPa)). Upon reception of this instruction, the pressure controller 525 of the pressure adjuster 520 halts the exhaust device 524 and opens the valve 521 with the valve 522 closed, thereby introducing the inert gas in the cylinder 530 into the tank unit 260. When the pressure in the tank unit 260 increases to the predetermined pressure P, the pressure controller 525 may adjust open/close of the valves 521 and 522 to perform a control for maintaining the pressure in the tank unit 260 at the predetermined pressure P. While the pressure in the tank unit 260 is kept at the predetermined pressure P, the target material 271 may be jetted out of the nozzle hole 267.

The controller 51 may then control the piezoelectric power supply 552 such that the target material 271 jetted out of the nozzle hole 267 changes into droplets in a predetermined size in a predetermined cycle. Consequently, desirable droplets may be supplied to the plasma generated region 25 (see FIG. 1) in the chamber.

### 5. Filter Portion

The filter portion 300 illustrated in FIG. 2 will now be described in detail referring to the drawings.

5.1 Configuration

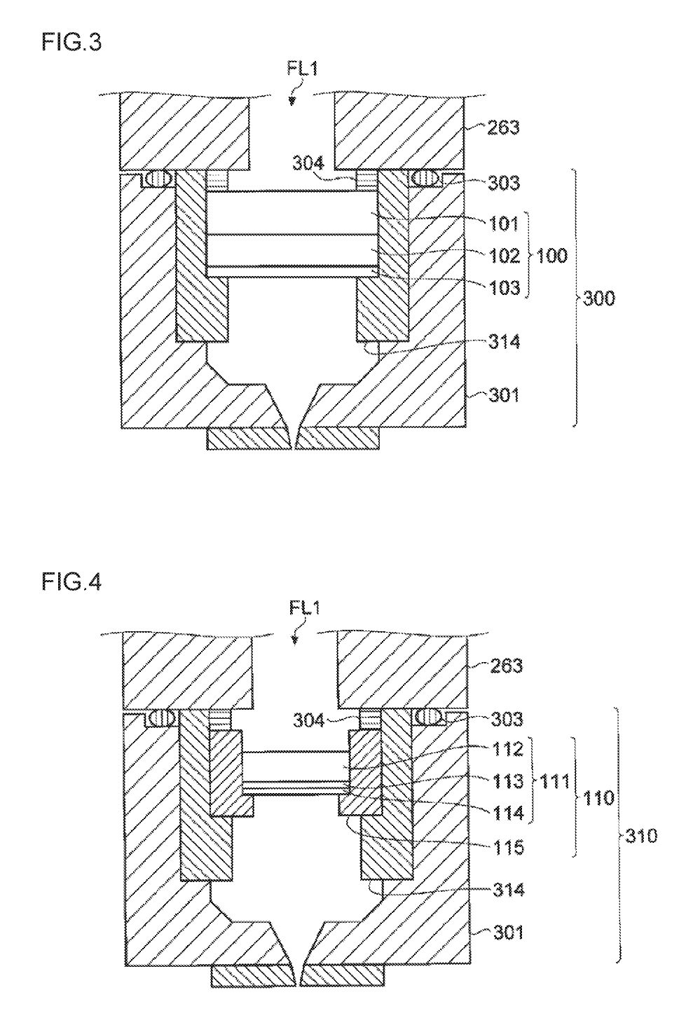

FIG. 3 is a cross-sectional view of an example of the schematic configuration of the filter portion.

As illustrated in FIG. 3, the filter portion 300 may include a flange 301, a multilayer filter 100, a filter holder 314, and at least one shim 304.

The materials for the flange 301 and the filter holder 314 may have low reactivity with the target material 271. This material having low reactivity with the target material 271 may be molybdenum (Mo), for example. The shim 304 may also be composed of a material (e.g., Mo) having low reactivity with the target material 271.

The flange 301 may have a cylindrical shape having the same diameter as the projection 263. The flange 301 may be fixed to the projection 263 of the tank unit 260 with the use of a bolt not illustrated in the drawing. An O ring 304 for sealing may be provided between the flange 301 and the projection 263. Note that the O ring 304 is optional. In other words, when plane sealing is formed between the flange 301 and the projection 263, the O ring 304 may not be provided. Alternatively, both the O ring 304 for sealing and plane sealing may be provided between the flange 301 and the projection 263.

A flow path FL1 in communication with the flow path FL1 in the projection 263 may be formed in the flange 301. The flow path FL1 in the flange 301 may have an enlarged portion to accommodate the multilayer filter 100. The multilayer filter 100 may be securely accommodated in the enlarged portion with the use of the filter holder 314 and at least one shim 304. Thus, the multilayer direction of the multilayer filter 100 may be substantially the same as the direction in which the flow path FL1 in the flange 301 extends. The filter holder 314 and the shim 304 may have a cylindrical or ring shape.

The surfaces of the flange 301 and the filter holder 314 in contact with each other may be polished surfaces. In addition, both sides of the shim 304, the surfaces of the projection 263 and the shim 304 in contact with each other, and the surfaces of the filter holder 314 and the shim 304 in contact with each other may be polished surfaces. These polished surfaces may be brought into contact with each other with the use of plane sealing.

The multilayer filter 100 may filter particles of tin oxide and the like contained in the target material 271. The multilayer filter 100 may have a multilayer structure with a plurality of filters. FIG. 3 illustrates the multilayer filter 100 composed of three filters 101 to 103 as an example.

The three filters 101 to 103 may be filters with filter hole diameters of 20 μm, 10 μm, and 6 μm, respectively, in sequence from the tank unit 260 side, for example. The filters 101 to 103 may be a porous material such as porous glass composed mainly of aluminum oxide- or silicon dioxide-based glass.

5.2 Operation

During the operation of the filter portion 300, when the liquid target material 271 flowing from the tank unit 260 to the flow path FL1 passes through the multilayer filter 100, the particles in the target material 271 may be filtered. This may remove the particles, which cause clogging of the nozzle hole 267 and destabilize the paths of the droplets 27, from the target material 271 flowing to the nozzle section 266.

5.3 Problem to be Solved

When a porous material is used as a filter, friction due to thermal expansion and shrinkage during assembly, heating, and cooling may cause a partial loss of the filter and thus generate particles. Particles from the filter 103, for example, may not be removed by the multilayer filter 100. These particles may reach the nozzle hole 267 and cause clogging of the nozzle hole 267 and destabilize the paths of the droplets 27. In view of this, the embodiments below illustrate a filter structure, a target generation device, and a method for manufacturing the filter structure which can restrain the generation of particles from the multilayer filter 100.

### 6. Embodiment 1

Embodiment 1 may include an intermediate member for mounting the multilayer filter on the filter holder 314. Hereinafter, the intermediate member will be referred to as a socket.

6.1 Configuration

FIG. 4 is a cross-sectional view of an example of the schematic configuration of the filter portion according to Embodiment 1. A configuration of the filter portion 300 different from the configuration in FIG. 3 will now be described.

As illustrated in FIG. 4, the filter portion 310 according to Embodiment 1 may have the same configuration as the filter portion 300 illustrated in FIG. 3 except that it includes a filter structure 110 instead of the multilayer filter 100.

The filter structure 110 may include a multilayer filter 111 and a socket 115.

The multilayer filter 111 may have a disc-shaped multilayer structure. This multilayer structure may be formed by a multilayer formation process. The multilayer structure may consist of three layers. FIG. 3 illustrates the case where the multilayer structure consists of three layers of 112 to 114.

The layers 112 to 114 may be composed of porous materials with different pore sizes. Alumina may be used as a porous material.

For the layers 112 to 114, the pore size may increase toward the upstream of the flow of the target material 271 (hereinafter also referred to as the upstream in the multilayer direction). For example, the layer 112 in the most upstream of the flow of the target material 271 may have a pore size of 12 μm. In this case, the pore size of the layer 113 may be 0.8 μm. The layer 114 in the most downstream of the flow of the target material 271 may have a pore size of 0.2 μm.

At least one of the layers 112 to 114 may be thicker than the other layers. For example, the layer 112 may be thicker than the layers 113 and 114. In this case, the layer 112 may act as a support for the layers 113 and 114 and the entire multilayer filter 111.

For the layers 112 to 114, the thickness may increase toward the upstream of the flow of the target material 271. The thickness of the layer 112 may be 2 mm In this case, the thickness of the layer 113 may be 30 μm, and the thickness of the layer 114 may be 20 μm.

The socket 115 may have a shape that can hold the multilayer filter 111 and can be accommodated in the filter holder 314. In this case, a contact between the socket 115 and the filter holder 314 may be present on the periphery of the side surface of the socket 115 in order to prevent the leakage of the target material 271.

The socket 115 may be a ring member composed of a bulk of the same material as the multilayer filter 111. For example, the socket 115 may be a dense alumina (alumina ceramic) body or single-crystal sapphire.

It should be noted that the porous rate of the layers 112 to 114 in the multilayer filter 111 may be, for example, 40 to 50%. Meanwhile, the socket 115 may have a porous rate of, for example, 2% or less.

Surfaces of the socket 115 and the filter holder 314 in contact with each other may be polished. This may provide plane sealing between the socket 115 and the filter holder 314.

The multilayer filter 111 and the socket 115 may be integrally formed by bonding. When the multilayer filter 111 and the socket 115 are composed of alumina, they may be bonded by thermal bonding or glass bonding. Alternatively, the multilayer filter 111 and the socket 115 may be bonded with an alumina adhesive and then fired.

6.2 Effect

In the above-described configuration, the filter structure 110 in which the multilayer filter 111 and the socket 115 are joined may be mounted on the filter holder 314. When the multilayer filter 111 is joined to the socket 115 in advance, the socket 115 is mounted on the filter holder 314. As described above, the socket 115 may be composed of a dense ceramic or single-crystal material. Accordingly, a partial loss of a porous material in the multilayer filter 111 due to friction can be reduced during assembly, heating, and cooling. Consequently, generation of particles during assembly, heating, and cooling, and therefore clogging of the nozzle hole 267 and destabilization of the paths of the droplets can be restrained.

### 7. Modification of Embodiment 1

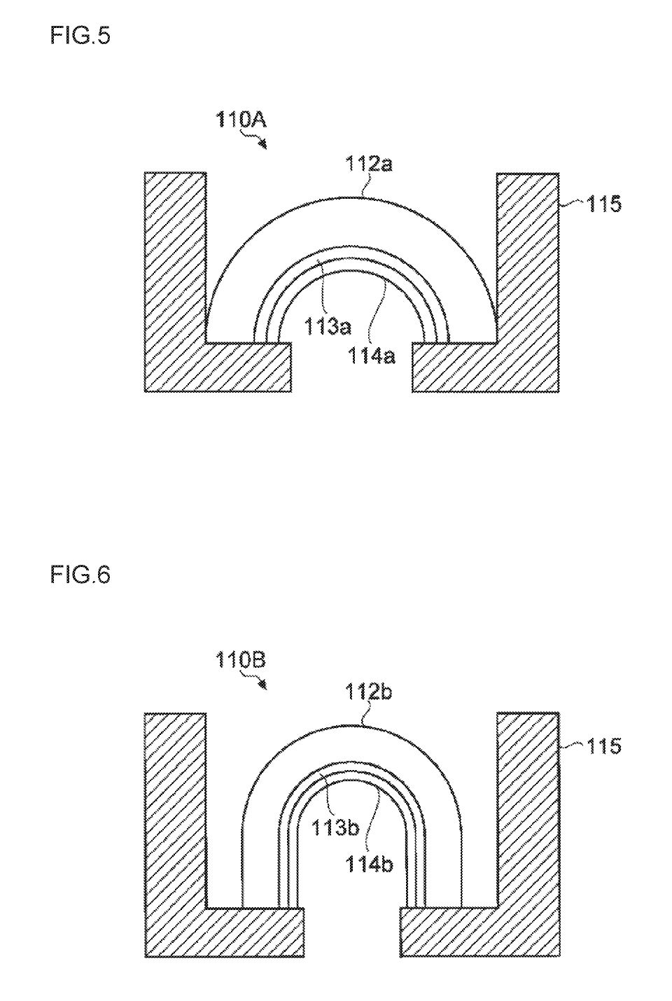

FIGS. 5 and 6 illustrate modifications of the multilayer filter 111 illustrated in FIG. 4. Configurations different from the configuration of the multilayer filter 111 in FIG. 4 will now be described.

7.1 Configuration

7.1.1 First Modification

FIG. 5 is a cross-sectional view of an example of the schematic configuration of a multilayer filter according to the first modification. As illustrated in FIG. 5, the multilayer filter 110A may be a domical filter having a multilayer structure. In FIG. 5, the material (properties), pore size, porous rate and thickness of a layer 112a in the most upstream of the flow of the target material 271 may be the same as those of the layer 112. Similarly, the materials (properties), pore sizes, porous rates and thicknesses of the layers 113a and 114a may be the same as those of the layers 113 and 114, respectively.

7.1.2 Second Modification

FIG. 6 is a cross-sectional view of an example of the schematic configuration of a multilayer filter according to the second modification. As illustrated in FIG. 6, a multilayer filter 110B has the same configuration as the multilayer filter 110A in FIG. 5 except that its cylindrical portion in the dome is extended. This cylindrical portion may be separated from the inner surface of the socket 115. The materials (properties), pore sizes, porous rates and thicknesses of the layers 112b to 114b may be the same as those of the layers 112 to 114, respectively.

7.1.3 Other Modifications

Modifications of the multilayer filter 111 may include, in addition to the above-described modifications, components in a pyramid shape or any other shapes.

7.2 Effect

The multilayer filter 111 having a domical or pyramid-shape may have a larger filtering area. This may improve the amount (rate) of the capture of particles from the target material 271. An increase in filtering area may increase the cycle of the exchange of the multilayer filter.

### 8. Embodiment 2

In Embodiment 2, a hollow cylindrical multilayer filter may be used.

8.1 Configuration

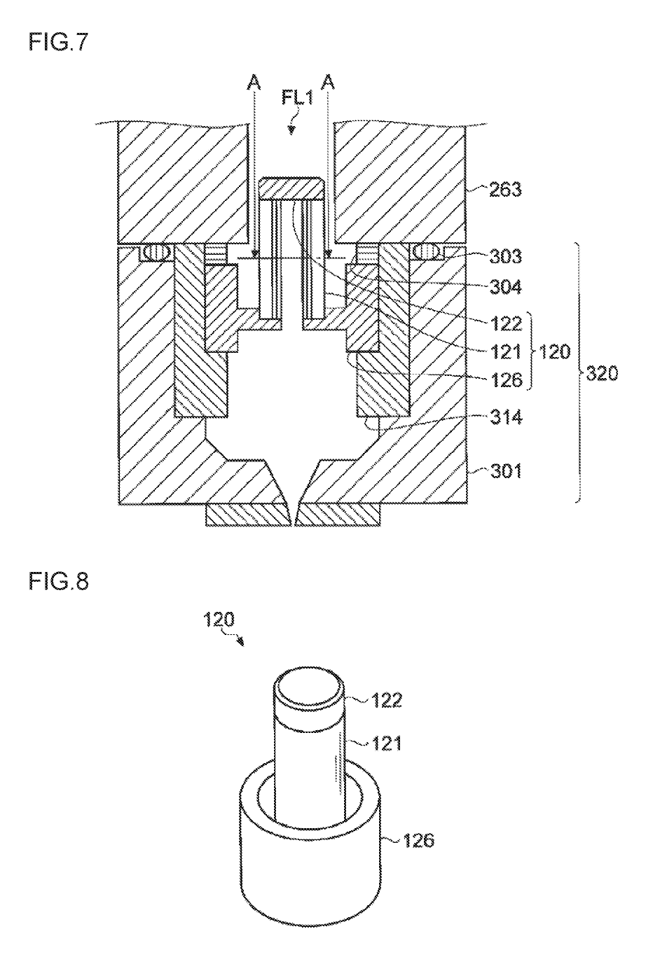

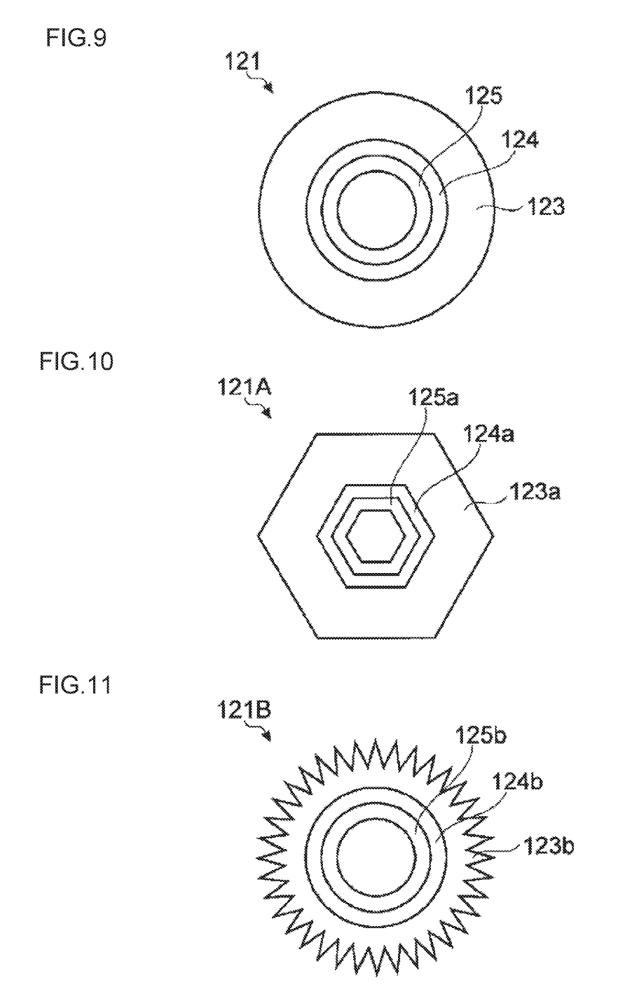

FIG. 7 is a cross-sectional view of an example of the schematic configuration of the filter portion according to Embodiment 2. FIG. 8 is a perspective view of an example of the schematic configuration of the filter structure illustrated in FIG. 7. FIG. 9 illustrates a cross-sectional structure of the multilayer filter in the filter structure in FIG. 8 along a face perpendicular to the direction in which the internal space extends. A configuration of the filter portion 310 different from the configuration in FIG. 4 will now be described.

As illustrated in FIG. 7, a filter portion 320 according to Embodiment 2 may have the same configuration as the filter portion 310 illustrated in FIG. 4 except that it includes a filter structure 120 instead of the filter structure 110.

As illustrated in FIG. 8, the filter structure 120 may include a multilayer filter 121, a cap 122, and a socket 126.

As illustrated in FIG. 9, the multilayer filter 121 may be a hollow cylindrical filter having a multilayer structure. The material (properties), pore size, porous rate and thickness of the outermost layer 123 in the most upstream of the flow of the target material 271 may be the same as those of the layer 112. Similarly, the materials (properties), pore sizes, porous rates and thicknesses of the layers 124 and 125 may be the same as those of the layers 113 and 114, respectively.

As illustrated in FIG. 8, the opening at one end of the hollow cylindrical multilayer filter 121 in the longitudinal direction may be sealed with a cap 122. The cap 122 may be a plate unit composed of a bulk of the same material as the multilayer filter 121. For example, the cap 122 may be a dense alumina (alumina ceramic) body or single-crystal sapphire.

The socket 126 may be provided to the other end of the multilayer filter 121 in the longitudinal direction. The socket 126 may have a shape that can hold the multilayer filter 121 and may be accommodated in the filter holder 314 without a space therebetween. The socket 126 may be composed of the same material as the socket 115 in Embodiment 1.

Surfaces of the socket 126 and the filter holder 314 in contact with each other may be polished. This may provide plane sealing between the socket 126 and the filter holder 314.

The multilayer filter 121 and the cap 122, and the multilayer filter 121 and the socket 126 may be integrally formed by bonding. The bonding may be performed in the same manner as the bonding between the multilayer filter 111 and the socket 115 in Embodiment 1.

As illustrated in FIG. 7, the filter structure 120 having such a configuration may be mounted on the filter holder 314 such that the cap 122 projects toward the flow path FL1 of the tank unit 260.

8.2 Effect

As in Embodiment 1, the filter structure 110 in which the multilayer filter 111 and the socket 115 are joined can be mounted on the filter holder 314, thereby restraining generation of particles during assembly, heating, and cooling. This can restrain clogging of the nozzle hole 267 and destabilization of the paths of the droplets.

### 9. Modification of Embodiment 2

The shape of the multilayer filter 121 according to Embodiment 2 is not limited to a hollow cylindrical shape. Modifications are described below.

9.1 Configuration

9.1.1 First Modification

FIG. 10 illustrates a cross-sectional structure of the multilayer filter of the first modification along a face perpendicular to the direction in which the internal space extends. As illustrated in FIG. 10, a multilayer filter 121A may have a regular hexagonal cross section including the flow path of the target material 271 in the center. The shape of the cross section is not limited to a regular hexagon and may be any polygon. The outline of the outermost layer 123a and the outlines of the inner layers 124a and 125a are not necessarily similar. To be specific, the layers 123 to 125 may have different cross sectional shapes. The materials (properties), pore sizes, porous rates and thicknesses of the layers 123a to 125a may be the same as those of the layers 112 to 114, respectively.

9.1.2 Second Modification

FIG. 11 illustrates a cross-sectional structure of the multilayer filter of the second modification along a face perpendicular to the direction in which the internal space extends. As illustrated in FIG. 11, in a multilayer filter 121B, the outline of the outermost layer 123b may be serrated with repeating recessed and protrude portions. The flow path of the target material 271 may be provided in the center. The outline of the outermost layer 123a and the outlines of the inner layers 124a and 125a are not necessarily similar. The materials (properties), pore sizes, porous rates and thicknesses of the layers 123b to 125b may be the same as those of the layers 112 to 114, respectively.

9.2 Effect

As described above, the shape of the cross section is changed to increase the perimeter of the outline of the cross section of the multilayer filter, which may further increase the amount (rate) of the capture of particles. The shape of the cross section of the multilayer filter may be changed as appropriate depending on the manufacturing method. The polygonal multilayer filter 121A illustrated in FIG. 10, for example, can be manufactured with a combination of plate-like members. The shape of the cap sealing the opening at one end of the multilayer filter may be changed as appropriate depending on the shape of the cross section of the multilayer filter.

### 10. Embodiment 3

In the configuration of Embodiment 2, the hollow cylindrical multilayer filter may not project toward the tank unit 260 but the nozzle section 266.

10.1 Configuration

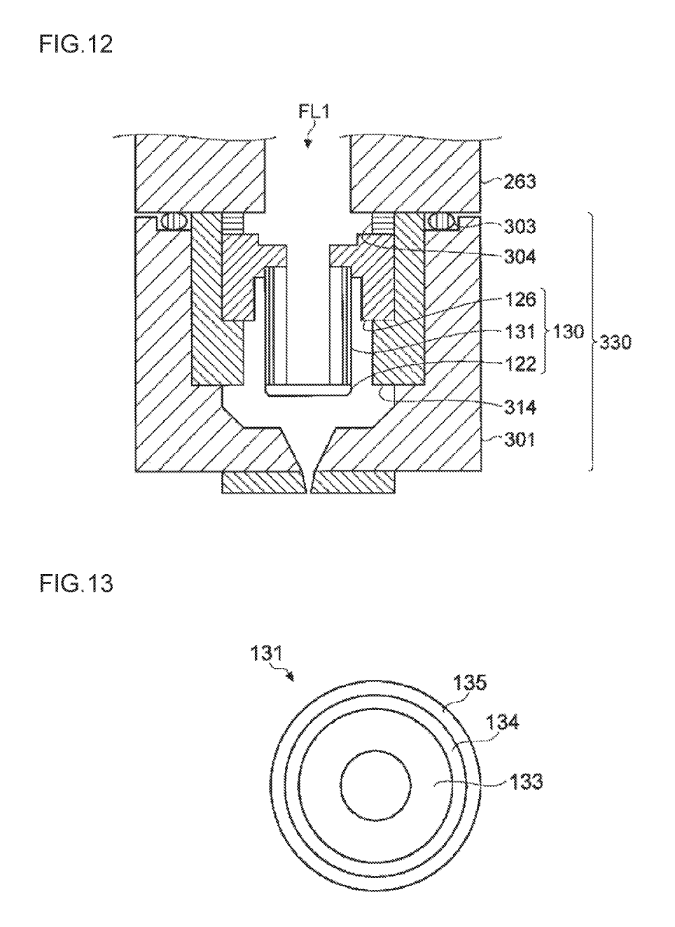

FIG. 12 is a cross-sectional view of an example of the schematic configuration of the filter portion according to Embodiment 3. FIG. 13 illustrates a cross-sectional structure of the multilayer filter in the filter portion in FIG. 12 along a face perpendicular to the direction in which the internal space extends. A configuration of the filter portion 320 different from the configuration in FIG. 7 will now be described.

As illustrated in FIG. 12, a filter portion 330 according to Embodiment 3 may have the same configuration as the filter portion 310 illustrated in FIG. 7 except that it includes a filter structure 130 instead of the filter structure 120. The filter structure 130 may have a configuration in which the portion of the filter structure 120 other than the multilayer filter 131 is vertically flipped.

As illustrated in FIG. 13, like the multilayer filter 121, the multilayer filter 131 may be a hollow cylindrical filter having a multilayer structure. For the layers 133 to 135 of the multilayer filter 131, since the positional relationship between the upstream and downstream of the flow of the target material 271 is inverted, the innermost layer 133 may reside in the most upstream, and the outermost layer 135 may reside in the most downstream. The materials (properties), pore sizes, porous rates and thicknesses of the layers 133 to 135 may be the same as those of the layers 112 to 114, respectively.

10.2 Effect

The configuration according to Embodiment 3 can provide the same effects and thus advantages as those provided by Embodiment 2.

### 11. Embodiment 4

In the above embodiment, the filter holder and the socket may be integrally formed. A configuration of the filter portion 320 based on but different from the configuration in FIG. 7 will now be described. Note that the integral formation of the filter holder and the socket illustrated in Embodiment 4 may be applicable to the other embodiments.

11.1 Configuration

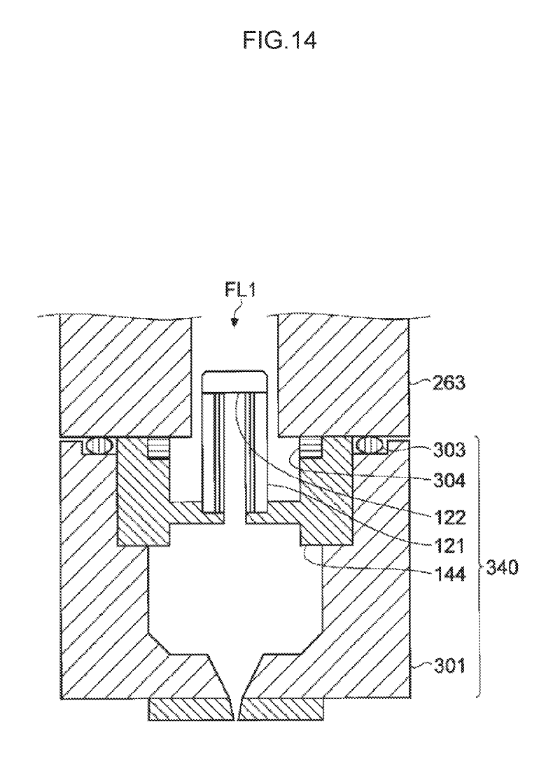

FIG. 14 is a cross-sectional view of an example of the schematic configuration of the filter portion according to Embodiment 4. As illustrated in FIG. 14, in a filter portion 340 according to Embodiment 4, the filter holder 314 and the socket 126 illustrated in FIG. 7 are replaced by the socket 144.

The socket 144 may have a shape that can hold the multilayer filter 121 and can be accommodated in the flange 301. In this case, a contact between the socket 144 and the flange 301 may be present on the periphery of the side surface of the socket 144 in order to prevent the leakage of the target material 271.

The socket 144 may be a ring member composed of a bulk of the same material as the multilayer filter 121. For example, the socket 144 may be a dense alumina (alumina ceramic) body or single-crystal sapphire.

Surfaces of the socket 144 and the flange 301 in contact with each other may be polished. This may provide plane sealing between the socket 144 and the flange 301.

The multilayer filter 121 and the socket 144 may be integrally formed by bonding. When the multilayer filter 121 is composed of alumina and the socket 144 is composed of alumina or single-crystal sapphire, they may be bonded by thermal bonding or glass bonding. Alternatively, the multilayer filter 121 and the socket 144 may be bonded with an alumina adhesive and then fired.

The socket 144 may have a groove to accommodate the shim 304. A surface of the flange 301 and a surface of the socket 144 in contact with each other may be polished surfaces. A surface of the socket 144 and a surface of the shim 304 in contact with each other may be polished surfaces. These polished surfaces may be brought into contact with each other with the use of plane sealing. When plane sealing is formed between the socket 144 and the projection 263, the shim 304 may not be provided.

11.2 Effect

Embodiment 4 provides the same advantages as those provided by the above embodiments and allows a component consisting of the filter holder and the socket to be replaced by one socket. Thus, the configuration of the filter structure can be simplified. This can result in a reduction in the cost of manufacturing the filter structure.

### 12. Embodiment 5

In the above embodiments, the socket may be formed by thermal spraying. A configuration of the filter portion 310 illustrated in FIG. 4 based on the configuration in which the filter holder 314 and the socket 115 are integrally formed and the socket is formed by thermal spraying will now be described. Note that the formation of the socket by thermal spraying illustrated in Embodiment 5 may be applicable to the other embodiments.

12.1 Configuration

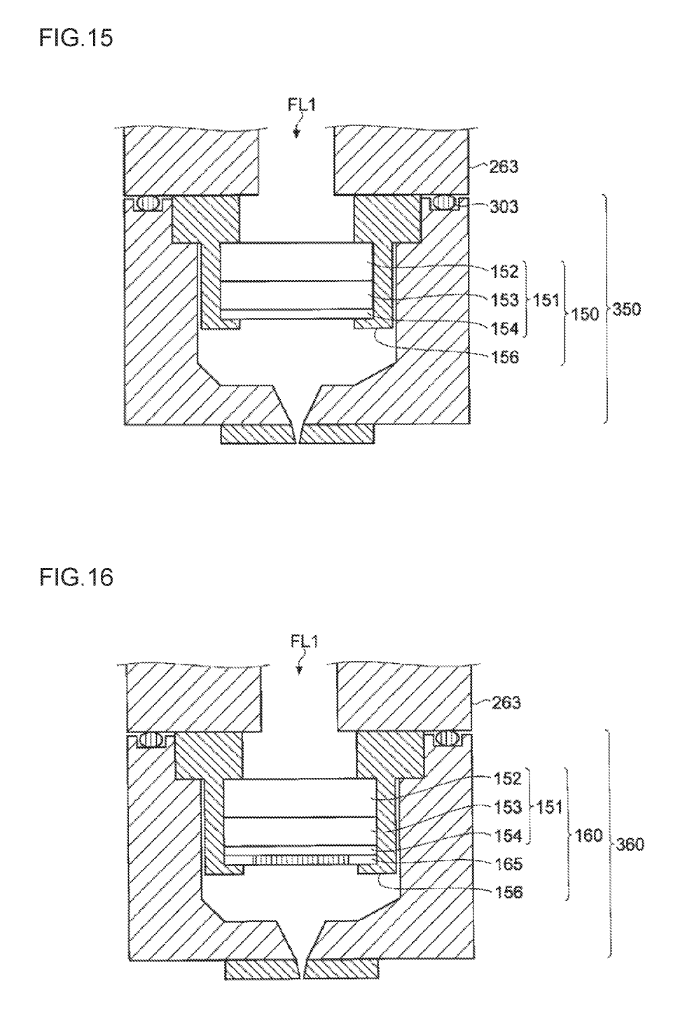

FIG. 15 is a cross-sectional view of an example of the schematic configuration of the filter portion according to Embodiment 5. As illustrated in FIG. 15, a filter portion 350 according to Embodiment 5 may have the same configuration as the filter portion 310 illustrated in FIG. 4 except that it includes a filter structure 150 instead of the filter structure 110 and the filter holder 314.

In other words, the filter holder 314 and the socket 115 may be replaced by a socket 156. In addition, the multilayer filter 111 may be replaced by a multilayer filter 151.

The multilayer filter 151 may have a structure in which first to third filters 152 to 154, which are different disc-like members, are stacked. The shapes, materials (properties), pore sizes, porous rates and thicknesses of the filters 152 to 154 may be the same as those of the layers 112 to 114, respectively. Note that the multilayer filter 151 may be replaced by the multilayer filter 100 or other multilayer filters.

The socket 156 may be a member formed by thermally spraying the multilayer filter 151. If the socket 156 is formed by thermal spraying, the filter structure 150 can be manufactured while the filters 152 to 154 are held united. A process for manufacturing the filter structure 150 by thermal spraying will be described later.

The socket 156 may have a shape that can hold the multilayer filter 151 and can be accommodated in the flange 301. In this case, a contact between the socket 156 and the flange 301 may be present on the periphery of the side surface of the socket 156 in order to prevent the leakage of the target material 271.

Like the flange 301, the socket 156 may be composed of a material (e.g., Mo) having low reactivity with the target material 271.

Surfaces of the socket 156 and the flange 301 in contact with each other may be polished. This may provide plane sealing between the socket 156 and the flange 301. A surface of the socket 156 and a surface of the projection 263 in contact with each other may be polished surfaces. This may provide plane sealing between the socket 156 and the projection 263. In this case, the shim 304 is not necessarily provided between the socket 156 and the projection 263.

12.2 Effect

When the socket 156 is formed by thermal spraying so that the socket 156 and the multilayer filter 151 can be integrally formed, the material for (properties of) the socket 156 may be determined independently of the material for (properties of) the multilayer filter 151. Accordingly, the material for (properties of) the socket 156 may be the same as the material for (properties of) the flange 301. When the socket 156 and the flange 301 are composed of the same material (properties), stress due to a difference in thermal expansion during assembly, heating, and cooling can be reduced. Consequently, generation of particles during assembly, heating, and cooling, and therefore clogging of the nozzle hole 267 and destabilization of the paths of the droplets can be restrained.

### 13. Embodiment 6

In the above embodiments, the multilayer filter may include a support plate that increases stiffness. A configuration of the filter portion 350 based on but different from the configuration illustrated in FIG. 15 will now be described. Note that the support plate illustrated in Embodiment 6 may be applicable to the other embodiments.

13.1 Configuration

FIG. 16 is a cross-sectional view of an example of the schematic configuration of the filter portion according to Embodiment 6. As illustrated in FIG. 16, a filter portion 360 according to Embodiment 6 may have the same configuration as the filter portion 350 illustrated in FIG. 15 except that the socket 156 further includes a support plate 165.

The support plate 165 may be a disc-like member having the same diameter as the first to third filters 152 to 154. The support plate 165 may be composed of glass or other materials (e.g., Mo) having low reactivity with the target material 271.

The support plate 165 may have a plurality of through holes in the center. The number of through holes may be, for example, 10 to 100. The pore size of the through holes may be, for example, about 100 to 1500 μm.

13.2 Effect

Since the multilayer filter 151 is supported by the support plate 165, the stiffness of the filter structure 160 can be increased. Hence, even with relatively high pressure on the target material 271 in the tank unit 260, for example, breakage of the multilayer filter 151 can be restrained.

### 14. Materials

In the above-described embodiments, alumina (or alumina ceramic) or single-crystal sapphire are described as example materials for the multilayer filter, the socket, and the cap. Other example materials will now be described.

14.1 Materials for Socket and Cap

The materials for the socket and the cap preferably satisfy following Conditions 1 and 2.
(1) Having low reactivity with the molten target material 271 (e.g. tin)
(2) Having a coefficient of thermal expansion near that of the flange 301

Table 1 illustrates example materials satisfying Condition 1.

TABLE 1

| | | | Coefficient of |
|---|---|---|---|
| | Filter | | thermal expansion |
| Filter | structure | Material | (×10⁻⁶/K) |
| Metal filter | Through hole | Molybdenum | 5.2 |
| | Through hole | Tungsten | 4.6 |
| Glass filter | Porous glass | Aluminum oxide- | 6 |
| | | silicon dioxide glass | |
| | | Quartz glass | 0.59 |
| | | Soda glass | 8.5-9.0 |
| | | Borosilicate glass | 3.2 |
| Ceramic | Porous ceramic | Alumina | 8.2 |
| filter | | Silicon carbide | 4.1 |
| | | Tungsten carbide | 5.2 |
| | | Aluminum nitride | 4.8 |
| | | Zirconium boride | 5.9 |
| | | Boron carbide | 5.4 |

As described above, a metal material for the flange 301 may be molybdenum (Mo) having low reactivity with the target material (e.g., tin). A material exhibiting a coefficient of thermal expansion near that of molybdenum may be selected from Table 1 as a material for the socket. The coefficient of thermal expansion near that of molybdenum may be in a range ±20% of the coefficient of thermal expansion of molybdenum. Table 1 illustrates such materials: silicon carbide, tungsten carbide, aluminum nitride, zirconium boride, and boron carbide.

14.2 Filter Material

The material for the multilayer filter may be the same as the material for the socket and have a different structure from that of the material for the socket. Alternatively, the material for the multilayer filter may be different from the material for the socket. The material for the multilayer filter preferably satisfies following Conditions 3 and 4 in addition to Conditions 1 and 2 for the materials for the socket and the cap.
(3) Able to have a porous structure
(4) Bondable to the material for the socket or cap

A material satisfying Conditions 1 to 4 may be selected from Table 1 as a material for the multilayer filter. Alternatively, any other materials satisfying Conditions 1 to 4 and having similar characteristics may be selected.

### 15. Process for Manufacturing Filter Structure by Thermal Spraying

A process for manufacturing a filter structure by thermal spraying illustrated in Embodiment 5 or 6 will now be described referring to the drawings. The description below takes a process for manufacturing the filter structure 160 according to Embodiment 6 as an example.

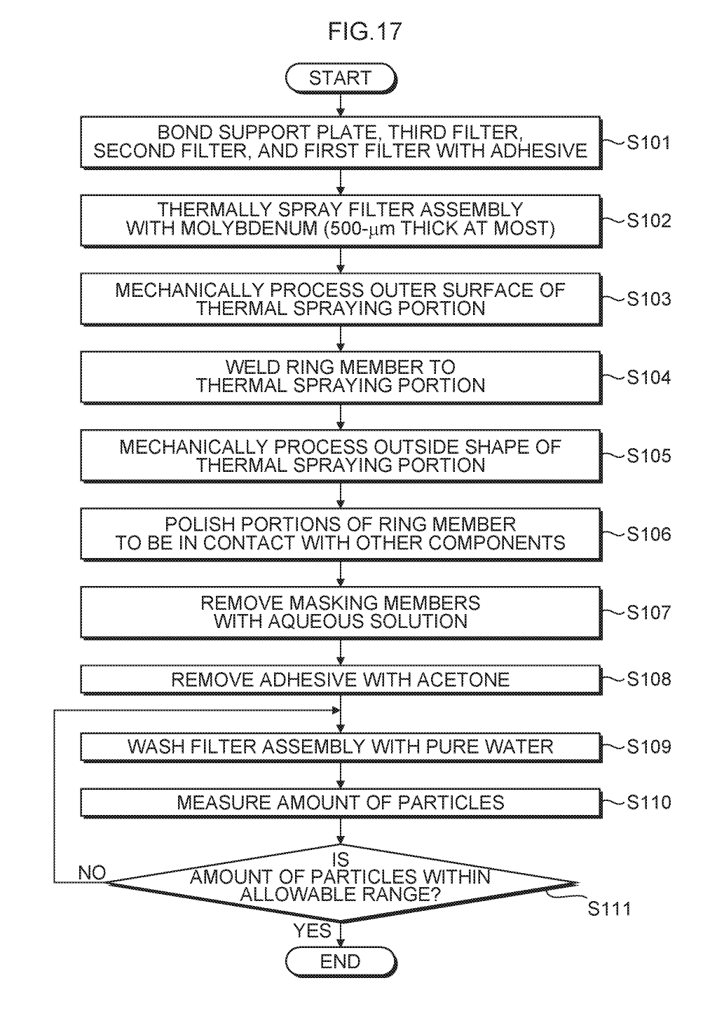

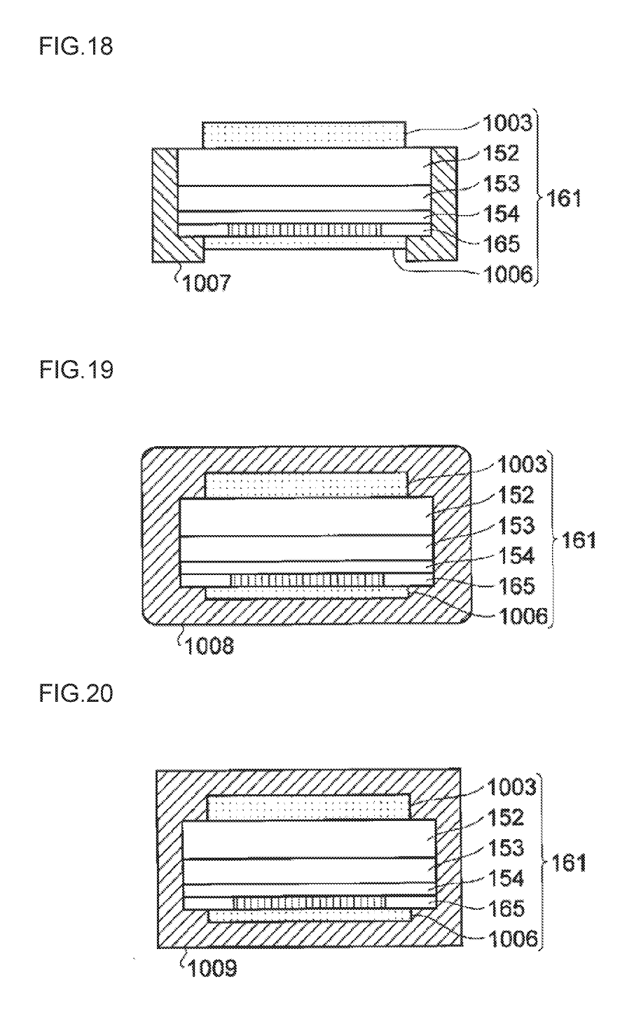

FIG. 17 is a flow chart of an example process for manufacturing a filter structure by thermal spraying. FIGS. 18 to 23 are cross-sectional views of the filter structure 160 during the main process, illustrating the manufacturing process illustrated in FIG. 17.

As illustrated in FIG. 17, in the process for manufacturing the filter structure 160, a support plate 165 having a masking member 1006, a third filter 154, a second filter 153, and a first filter 152 having a masking member 1003 may be bonded to each other with an adhesive (Step S101). At this time, as illustrated in FIG. 18, a third jig 1007 may be used as a support. The adhesive may be a cyanoacrylate-based adhesive. The adhesive may be any other adhesive which can be removed with a solution and the like. This may result in a filter assembly 161 (see FIG. 18) in which the multilayer filter 151 consisting of the first to third filters 152 to 154 is bonded to the support plate 165. The filter assembly 161 may include the masking members 1003 and 1006.

As illustrated in FIG. 19, the entire outer surface of the filter assembly 161 may be thermally sprayed with a socket material to form a thermal spraying portion 1008 (Step S102). The socket material may be molybdenum. The thickness of the socket material after thermal spraying may be about 500 μm at most.

As illustrated in FIG. 20, the outer surface of the thermal spraying portion 1008 may be then mechanically processed (Step S103). The outside diameter of the thermal spraying portion 1009 after processing may be the same as that of itself after completion of the filter structure 160.

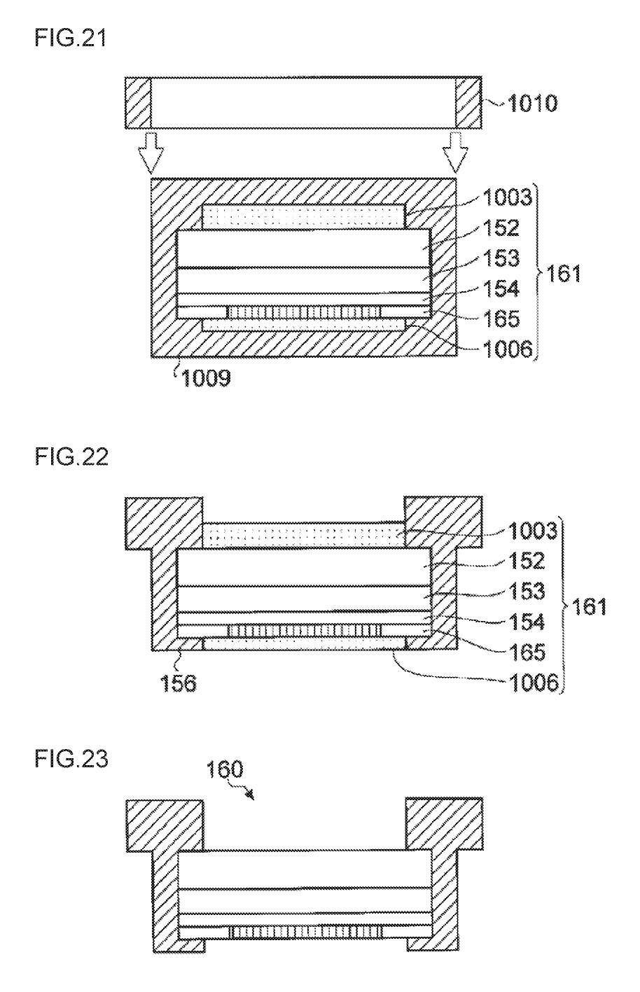

As illustrated in FIG. 21, a ring member 1010 that allows the filter structure 160 to engage with the flange 301 may be then welded to the thermal spraying portion 1009 (Step S104).

As illustrated in FIG. 22, the outside shape of a holding portion 1009 may be then mechanically processed (Step S105). This may expose the masking members 1003 and 1006 of the filter assembly 161.

Portions of the welded ring member 1010 which is to be in contact with the flange 301 and the projection 263 may be polished (Step S106).

As illustrated in FIG. 23, the exposed masking members 1003 and 1006 may be removed with a solution (Step S107). This may complete the filter structure 160. The adhesive may be then removed with a solution (Step S108).

The filter structure 160 may be then washed with pure water or the like (Step S109) and the amount of particles remaining on the filter structure 160 after washing may be measured (Step S110). Washing of the filter structure 160 may be repeated (Step S111: NO) until the measured amount of particles falls within a predetermined allowable range (Step S111: YES).

The above description should not be construed to be limitations but illustrative only. Accordingly, it should be understood by those skilled in the art that modifications of the embodiments of the present disclosure can be made without departing from the attached claims.

The terms used in the entire description and attached claims should be construed to be “non-restrictive”. For example, the term such as “include” or “included” should be construed to mean “include, but should not be limited to”. The term “have” should be construed to mean “have, but should not be limited to”. The indefinite article “a” in the description and attached claims should be construed to mean “at least one” or “one or more”.

What is claimed is:

1. A target generation device comprising:
a filter structure including a filter containing a porous material and a socket integrally formed with the filter by bonding;
a flange accommodating the filter structure and containing a flow path passing through the filter structure;
a tank unit containing a space in communication with the flow path in the flange and storing a predetermined target material; and
a nozzle section provided to the flange and in communication with the space in the tank unit through the flow path in the flange,
the filter having a porous rate higher than a porous rate of the socket.

2. The target generation device according to claim 1, wherein the filter and the socket are integrally formed by thermal bonding.

3. The target generation device according to claim 1, wherein the filter and the socket are integrally formed by glass bonding.

4. The target generation device according to claim 1, wherein the filter and the socket are integrally formed by thermally spraying the filter with a material for the socket.

5. The target generation device according to claim 1, wherein the filter and the socket contain materials having the same coefficient of thermal expansion.

6. The target generation device according to claim 1, wherein the filter and the socket contain the same material.

7. The target generation device according to claim 1, wherein
the filter contains alumina, and
the socket contains a dense alumina body or a sapphire single crystal.

8. The target generation device according to claim 1, wherein
the socket contains a material containing at least one of molybdenum and tungsten, and
the filter contains porous glass containing aluminum oxide-silicon dioxide glass.

9. The target generation device according to claim 1, wherein the filter has a multilayer structure including a plurality of layers having different pore sizes.

10. The target generation device according to claim 9, wherein among the plurality of layers, a layer on one side in a multilayer direction has the largest pore size, and a layer on the other side in the multilayer direction has the smallest pore size.

11. The target generation device according to claim 1, wherein the filter has a multilayer structure with a plurality of filters having different pore sizes.

12. The target generation device according to claim 1, wherein the filter has a disc shape.

13. The target generation device according to claim 1, wherein the filter has a domical shape.

14. The target generation device according to claim 1, wherein
the filter forms a hollow structure opened at both ends in a longitudinal direction,
the target generation device further comprises a cap sealing an opening at one end of the filter in the longitudinal direction, and
the socket is provided at the other end of the filter in the longitudinal direction.

15. The target generation device according to claim 14, wherein the filter is circular in a cross section along a direction perpendicular to the longitudinal direction.

16. The target generation device according to claim 14, wherein the filter is polygonal or serrated in a cross section along a direction perpendicular to the longitudinal direction.

17. The target generation device according to claim 1, wherein
the filter has a multilayer structure including a plurality of layers having different pore sizes,
the flange holds the filter such that a multilayer direction of the filter is identical to a direction in which the flow path in the flange extends, and
among the plurality of layers, the layer adjacent to the tank unit along the flow path has the largest pore size, and the layer adjacent to the nozzle section along the flow path has the smallest pore size.

18. A method for manufacturing a filter structure having a filter containing a porous material and used in a target generation device, comprising:
stacking the filter partly covered by a masking member;
thermally spraying an outer surface of the filter partly covered by the masking member with a material having approximately the same coefficient of thermal expansion as the filter;
processing the material to partly expose the masking member; and
removing the masking member.
